(19) United States
(12) Patent Application Publication
(10) Pub. No.: US 2005/0184620 A1
(43) Pub. Date: Aug. 25, 2005

(54) Simple method of designing acoustic matching layers in thickness-mode piezoelectric transducers

(75) Inventors: Myoung Seon Choi, Soosung-gu (KR); Soon Sin Hong, Daejeon (KR); Chi Seung Park, Daejeon (KR)

Correspondence Address: Ladas & Parry, 26 West 61st Street, New York, NY, 10023, US

(73) Assignees: KAITEC INC.; YEUNGNAM UNIVERSITY

(21) Appl. No.: 10/782,468

(22) Filed: Feb. 19, 2004

(51) Int. Cl. H01L 41/08; H01L 41/04

(52) U.S. Cl. 310/311

(57) ABSTRACT

The present invention relates to an optimum designing method of matching layers of a thickness-mode piezoelectric transducer in which a front load effective impedance when viewing in a load direction from a front side of a piezoelectric plate is used as a design parameter when designing an acoustic matching layer. An impedance characteristic of each acoustic matching layer is determined using a new matching formula. An optimized design parameter is determined in a region in which an amplitude in a peak amplitude contour map and a depth of a pulse width contour map using video waveforms for statistically evaluating a sensitivity and resolution of a piezoelectric transducer.

### BACKGROUND OF THE INVENTION

1. Field of the Invention

The present invention relates to an optimum designing method of matching layers, and in particular to a simple method of designing acoustic matching layers in thickness-mode piezoelectric transducers capable of achieving optimum input impedance when designing matching layers used in a thickness-mode piezoelectric transducer.

2. Description of the Background Art

Generally, an ultrasonic transducer has been widely used in various fields such as medical diagnosis, underwater detection, nondestructive evaluation, etc. As shown in FIG. 1, a piezoelectric transducer 10 basically includes a piezoelectric plate 12, a back absorption layer 14, and one or more front acoustic matching layers 16, an electric matching device 18 (for example, a series or shunt inductor), and other related elements.

The piezoelectric plate 12 a ceramic group electric device capable of transforming electric pulse signals into acoustic pulse signals. The back absorption layer 14 is an acoustic absorption layer capable of preventing an echo phenomenon of the piezoelectric plate 12. The electric matching device 16 is an electric device capable of matching electric impedance with external electric equipment. The front acoustic matching layer 18 is a thin layer structure inserted in order that sound waves generated in the piezoelectric plate 12 can be well transferred in the direction of a front load 20 (for example, in the case of nondestructive evaluation, it is referred to a tested object, and in the case of the medical diagnosis, it is referred to human body).

In the thusly-constituted ultrasonic transducer, the most important characteristics are sensitivity (size of transmission and receiving signal), and a pulse width (time lapse of transmission pulse). The quality of the ultrasonic transducer is largely depended on the above two characteristics. The electromechanical performance of the transducer is largely depended on the optimization of each element belonging to the transducer. However, since it needs a lot of time and cost for determining the optimum combination of each element through experiment and actual fabrication, it is preferred to design through numeral computation using algorithm capable of predicting the characteristics of ultrasonic transducer. Among many algorithms, a matching layer designing method implemented based on the transmission line theory is suggested by Krimholtz etc. and has been most widely used.

The computer program adapting the KLM model for optimizing piezoelectric transducers has the following parameters.
electrostatic capacitance (C₀) of piezoelectric plate, sound wave speed (Vc), acoustic impedance (Z_{c}), cross section region (A), free resonant frequency (f₀) and electric mechanical coupling coefficient (kₜ)
acoustic impedance (Zₜ) of front load material, and acoustic impedance (Z_{b}) of back absorption layer material
impedance (Lₛ) of series inductor
number (n) of acoustic matching layer, impedance (Zᵢ) of the i-th matching layer in the direction from piezoelectric plate to the front load, and band pass central frequency (f₀^{(a)}).

The following table 1 shows a matching formula of a matching layer impedance proposed by Desilets.

TABLE 1

| | Impedance | | |
|---|---|---|---|
| Number of layers | Z₁ | Z₂ | Z3 |
| 1 | (Z_{c})^{1/3} (Zₜ)^{2/3} | | |
| 2 | (Z_{c})^{4/7} (Zₜ)^{3/7} | (Z_{c})^{1/7} (Zₜ)^{6/7} | |
| 3 | (Z_{c})^{11/15} (Zₜ)^{4/15} | (Z_{c})^{1/3} (Zₜ)^{2/3} | (Z_{c})^{1/15} (Zₜ)^{14/15} |

Where Z_{f} represents a front load effective impedance when it is viewed from the front side of the piezoelectric plate, and (Z_{f})⁽⁰⁾ is Z_{f} at a free resonant frequency. The matching layer designing method proposed by Desilets (table1) is implemented based on the KLM equivalent circuit in which the halves of the front and back sides of the piezoelectric plate is respectively considered as ¼ wavelength matching layers. In the designing method of Desilets, the impedance (Zᵢ) of the acoustic Is matching layer and the front load effective impedance (Z_{f})⁽⁰⁾ is at a free resonant frequency are dependent on the impedance (Z_{c}) of the piezoelectric plate and the impedance (Zₜ) of the front load. In the case of Zₜ<Z_{c}, the front load effective impedance (Z_{f})⁽⁰⁾ is increased as the number of the matching layers is increased.

FIG. 2 is a view illustrating a variation of the frequency spectrums of ultrasonic transducers based on the number of matching layers determined by the conventional matching formula of Desilets. The piezoelectric plate used in the computation is LM (Lead Metaniobate) disk (electrostatic capacitance C₀=44 nF, frequency constant N_{f}=1525, Z_{c} is 19 Mray1, central frequency f₀ is 2.0 MHz, and electromechanical coupling coefficient kₜ is 0.3). The front load and back material are a transparent synthetic resin (Lucite) (front load impedance Zₜ=3.2 Mray) and urethane-tungsten carbide compound (back absorption layer impedance Z_{b}=4.5 MRay1). The series inductance of the electric matching network is 15 μH.

As shown in FIG. 2, it is shown that the matching layer of the first layer provides the widest frequency bandwidth. Namely, additionally providing a matching layer may decrease the frequency bandwidth. Considering the ultrasonic wave transfer in view of the acoustic point, as the number of matching layer is increased, the frequency bandwidth should be increased. However, in an actual situation, the above matter does not occur due to the electric characteristic of the piezoelectric plate. As shown in Table 1, as the number of matching layer is increased, the effective impedance (Z_{f})⁽⁰⁾ of the front load is increased when viewing from the front side of the piezoelectric plate. Therefore, the results of FIG. 2 strongly suggest that there is the optimum front load effective impedance capable of providing the most excellent electric acoustic characteristic.

However, in the current ultrasonic transducer designing method using the matching formula of Desilets considering only the acoustic impedances of the piezoelectric plate and the front load, since the front load effective impedance (Z_{f})⁽⁰⁾ is non-continuously changed based on the number of the matching layers, it is impossible to select the optimum value.

Namely, in the conventional matching layer designing method, since only the acoustic characteristic of the piezoelectric plate is considered without considering the electrical characteristic, even when the number of the matching layers is increased, there is not any improvement in the energy transfer efficiency and bandwidth. Namely, it may be opposed to a general direct prediction.

### SUMMARY OF THE INVENTION

Accordingly, it is an object of the present invention to provide an optimum designing method of matching layers of a thickness-mode piezoelectric transducer capable of overcoming the problems encountered in the conventional art and capable of optimizing the performance of a thickness-mode piezoelectric transducer using KLM model.

It is another object of the present invention to provide an optimum designing method of matching layers of a thickness-mode piezoelectric transducer capable of enhancing an electric acoustic characteristic of a piezoelectric transducer in such a manner that a matching layer having an optimum impedance is newly designed in consideration with an ultrasonic characteristic and an electric characteristic of a piezoelectric plate when designing matching layers of a thickness-mode piezoelectric transducer.

It is further object of the present invention to provide an optimum designing method of matching layers of a thickness-mode piezoelectric transducer capable of designing matching layers in which a front load effective impedance viewed from the front side of a piezoelectric plate with respect to a piezoelectric material and a back material are not changed based on the number of layers.

To achieve the above objects, in a designing method of an acoustic matching layer of a piezoelectric transducer including a piezoelectric plate that is an electric device of a ceramic group capable of converting an electric pulse into a sound wave pulse signal, a back absorption layer that is a sound wave absorption layer for preventing an echo phenomenon of the piezoelectric plate, one or more acoustic matching layers formed in a thin layer structure constructed in order that sound waves generated in the piezoelectric plate can be transferred in the direction of a front load (in the case of nondestructive evaluation, it is referred to a tested object, and in the case of medical diagnosis, it is referred to human body), and an electric matching device that is an electric device for matching an external electric equipment and electric impedance, so that the present invention is well adapted to various fields such as medical diagnosis, underwater detection, nondestructive evaluation, etc., there is provided an optimum designing method of matching layers of a thickness-mode piezoelectric transducer that is characterized in that a front load effective impedance when in the direction of load from a front side of the piezoelectric plate as a design parameter when designing acoustic matching layers, and an impedance characteristic of each acoustic matching layer is determined using the following matching formula (3) shown in the following table 2.

In addition, when designing the acoustic matching layers of the piezoelectric transducer, a video waveform, not a RF waveform, is used for evaluating sensitivity and pulse width of the piezoelectric transducer, and an optimized design parameter is determined in a region in which an amplitude in a peak amplitude contour map and a depth in a pulse width contour map are duplicated for optimizing the design parameter.

To achieve the above objects, in a designing method of an acoustic matching layer of a piezoelectric transducer including a piezoelectric plate that is an electric device of a ceramic group capable of converting an electric pulse into a sound wave pulse signal, a back absorption layer that is a sound wave absorption layer for preventing an echo phenomenon of the piezoelectric plate, one or more acoustic matching layers formed in a thin layer structure constructed in order that sound waves generated in the piezoelectric plate can be transferred in the direction of a front load (in the case of nondestructive evaluation, it is referred to a tested object, and in the case of medical diagnosis, it is referred to human body), and an electric matching device that is an electric device for matching an external electric equipment and electric impedance, so that the present invention is well adapted to various fields such as medical diagnosis, underwater detection, nondestructive evaluation, etc., there is provided an optimum designing method of matching layers of a thickness-mode piezoelectric transducer, comprising the steps of: (1) a step in which a certain front load effective impedance is inputted, and a sensitivity, pulse width and performance index of a piezoelectric transducer are computed based on a KLM model computation; (2) a step in which a minimum value of a front load effective impedance is selected based on a sensitivity, pulse width and performance index of the piezoelectric transducer computed in the step (1); (3) a step in which a minimum value of the front load effective impedance is inserted into the matching formula shown in the following table obtained based on the following formula; and (4) a step in which an impedance computed in the step (3) is determined as an impedance of each layer.

### BRIEF DESCRIPTION OF THE DRAWINGS

The present invention will become better understood with reference to the accompanying drawings which are given only by way of illustration and thus are not limitative of the present invention, wherein;

FIG. 1 is a view illustrating the construction of a conventional ultrasonic transducer;

FIG. 2 is a view illustrating variation of frequency spectrum of a ultrasonic transducer based on the number of the matching layers determined by matching formula of Desilets;

FIG. 3 is a view illustrating KLM model of a thickness-mode piezoelectric transducer employed in the present invention;

FIG. 4 is a view illustrating a RF waveform and a frequency spectrum with respect to an optimized piezoelectric transducer according to the present invention;

FIG. 5 is a view illustrating a result of the computation of a relative sensitivity, pulse width and performance index when all designing parameters are in FIG. 2 except for matching layers and front loads according to the present invention;

FIG. 6 is a view illustrating a frequency spectrum variation of a piezoelectric transducer based on the number of matching layers determined by a new matching formula according to the present invention;

FIG. 7 is a view illustrating a video waveform change of a piezoelectric transducer based on a front load effective impedance value (Z_{f})⁽⁰⁾;

FIG. 8 is a view illustrating a peak amplitude with respect to a piezoelectric transducer having one matching layer and a contour map of 80 dB pulse width according to the present invention;

FIG. 9 is a view illustrating a peak amplitude with respect to a piezoelectric transducer having two matching layers and a contour map of 80 dB pulse width according to the present invention; and

FIG. 10 is a view illustrating a RF waveform of an optimized transducer and a frequency spectrum according to the embodiments of FIGS. 8 and 9 according to the present invention.

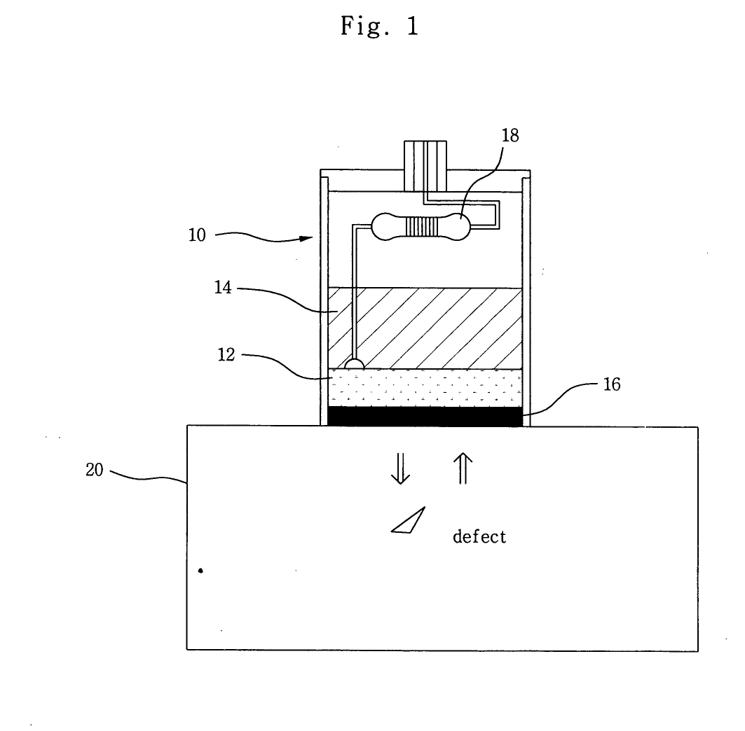

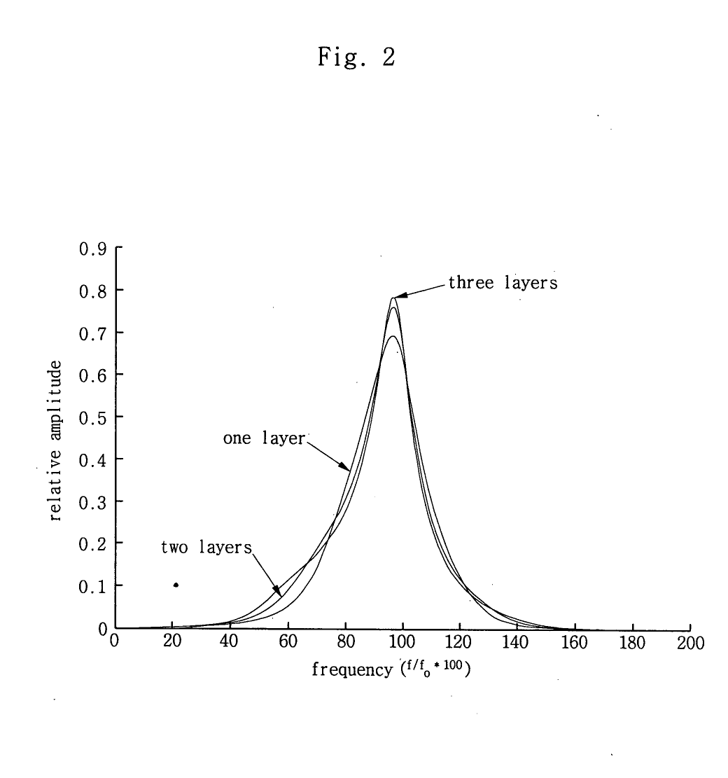

### DETAILED DESCRIPTION OF THE PREFERRED EMBODIMENTS

The optimum designing method of matching layers of a thickness-mode piezoelectric transducer according to the present invention will be described with reference to the accompanying drawings.

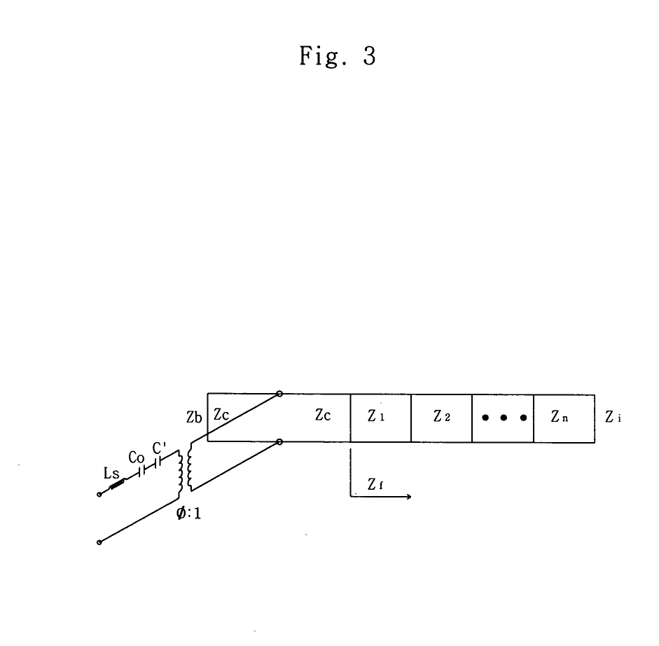

FIG. 3 is a view illustrating KLM model of a thickness-mode piezoelectric transducer employed in the present invention. Here, the electric transformer ratio φ and the capacitance C′ are given based on the following formulas 1 and 2.

$$\begin{matrix}ϕ = {k}_{i} \sqrt{\frac{π}{{ω}_{0} {C}_{0} {Z}_{0} A}} sin c ( ω / 2 {ω}_{0} ) & ( 1 ) \\ {C}^{′} = \frac{- {C}_{0}}{{k}_{i}^{2} sin c ( ω / {ω}_{0} )} & ( 2 )\end{matrix}$$

where sin c(x)=sin (πx)/πx.

The effective impedance of the front load viewed from the front side of the piezoelectric plate is indicated by Z_{f}.

The acoustic matching layer is designed using a binomial quarter-wave transformer in such a manner that the central frequency is positioned at the free resonant frequency of the piezoelectric plate, and the effective impedance of the front load at the above frequency has a real number of (Z_{f})⁽⁰⁾. In the present invention, (Z_{f})⁽⁰⁾ is used as a design parameter for the performance optimization of the transducer instead of the characteristic impedance of the matching layer.

The characteristic impedance of the matching layer with respect to a pair of (Z_{f})⁽⁰⁾ and (Zₜ) is determined based on the following formula 3 proposed by Goll.

$$ln \frac{{Z}_{i + 1}}{{Z}_{i}} = {2}^{- n} {C}_{i}^{n} ln \frac{{Z}_{t}}{{Z}_{f}^{( 0 )}} \qquad ( 3 )$$

where i=0, . . . , n, Z₀₌(Z_{f})⁽⁰⁾, Zₙ+1=Zₜ, Cᵢⁿ=n!/(n−1)!|!

The following table 2 shows the impedance matching formula according to the present invention obtained as a result until n=3. In the case of (Z_{f})⁽⁰⁾=Z_{c}.

TABLE 2
Impedance matching formula based on a
designing method according to the present invention.

| | Impedance | | |
|---|---|---|---|
| Number of layers | Z₁ | Z₂ | Z3 |
| 1 | (Z_{f})⁽⁰⁾ (Zₜ)^{1/2} | | |
| 2 | (Z_{f})^{(0)3/4} (Zₜ)^{1/4} | (Z_{f})^{(0)1/4} (Zₜ)^{3/4} | |
| 3 | (Z_{f})^{(0)7/8} (Zₜ)^{1/8} | (Z_{f})⁽⁰⁾ (Zₜ)^{1/2} | (Z_{f})^{(0)1/8} (Zₜ)^{7/8} |

Where Z_{f} represents an effective impedance of front load viewed from the front side of the piezoelectric plate, and (Z_{f})⁽⁰⁾ is (Z_{f}) at the free resonant frequency, and (Zₜ) is a front load impedance, and the above results are obtained until n=3.

In the impedance matching formula according to the designing method of the present invention through the table 2, the impedance (Zᵢ) of each matching layer is different from the impedance (Zₜ) as compared to the matching formula of Desilets. The impedance (Zᵢ) of each matching layer is dependent only on the effective impedance (Z_{f})⁽⁰⁾ of the front load. The optimum value of the front load effective impedance (Z_{f})⁽⁰⁾ may be achieved by performing a simulation with respect to an impulse response characteristic of the ultrasonic transducer using the KLM model.

In the present invention, a video waveform given based on amplitude, not a RF waveform given based on real numbers of time response conventionally used, is used.

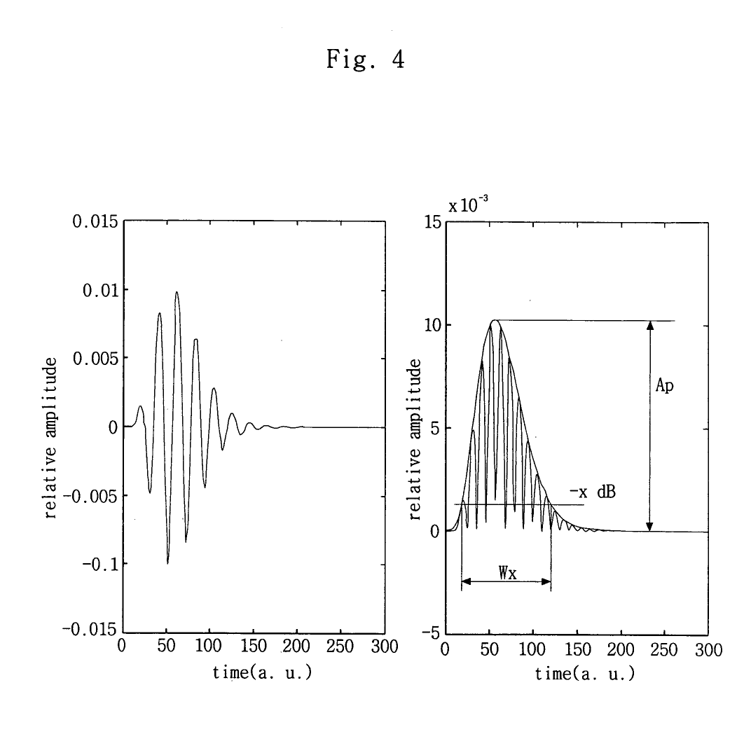

As shown in FIG. 4, the video waveform shows an envelope of rectified RF waveform. Namely, it is possible to statistically evaluate an impulse response characteristic of ultrasonic transducer using video waveforms simply increased or decreased with a positive peak value as compared to a RF signals that vibrates with two peak values of negative and positive values. The relative sensitivity of the transducer representing a ratio of response echo amplitude with respect to an electric impulse having a unit amplitude will be defined in the following formula 4.
Sᵣ=20 log(Aₚ) (4)

Where Aₚ represents a peak amplitude of video waveform.

The relative sensitivity always has a negative value. In addition, the performance index of the transducer may be defined in the following formula 5.
Pₓ=|Sᵣ|Wₓ (5)

Where Wₓ represents a pulse width corresponding to −x dBdp of peak amplitude. As the sensitivity and pulse width of the transducer are stable, both |Sᵣ| and Wₓ are decreased, so that the performance index is decreased.

In order to search the optimum values (z_{f})^{(d)} of the effective impedance (Z_{f})⁽⁰⁾ of the front load at the free resonant frequency with respect to the given piezoelectric plate and the back absorption layer, the case that there is not matching layer is first considered. In this case, the front load effective impedance (Z_{f}) has a constant real number value at all frequencies. (Z_{f})=(Zₜ), (Z_{f}) is systematically changed, and the relative sensitivity, pulse width and performance index are computed, and (Z_{f})^{(d)} is obtained from a result of the above computation.

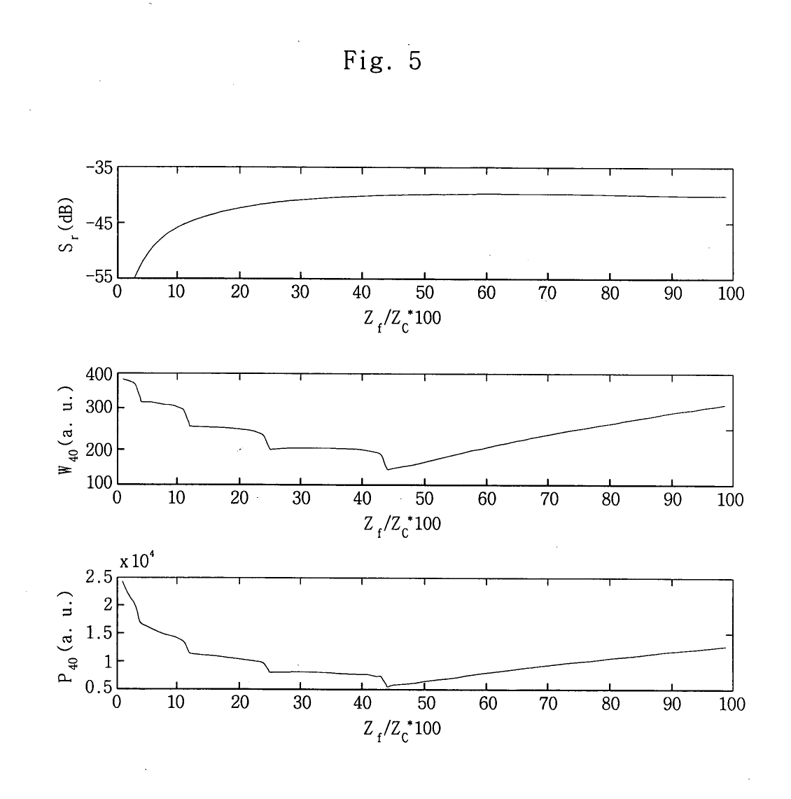

For example, FIG. 5 is a view of a result of computation of the relative sensitivity, pulse width, and performance index when all design parameters except for the matching layer and front load are same as the values of FIG. 2. The relative sensitivity Sᵣ is increased together with the front load effective impedance (Z_{f}). Therefore, it is known that there are the front load effective impedance (Z_{f}) providing the most excellent pulse width and the minimum performance index. (Z_{f}=0.43 Z_{c}) corresponds to the common type ultrasonic transducer. In the case of a high sensitivity ultrasonic transducer, the front load effective impedance value (Z_{f}) providing a high relative sensitivity and a proper pulse width is determined as the optimum value (Z_{f})^{(d)}, and in the case of a high resolution ultrasonic transducer, the front load effective impedance value (Z_{f}) providing a narrow pulse width and a proper relative sensitivity is determined as the optimum value (Z_{f})^{(d)}.

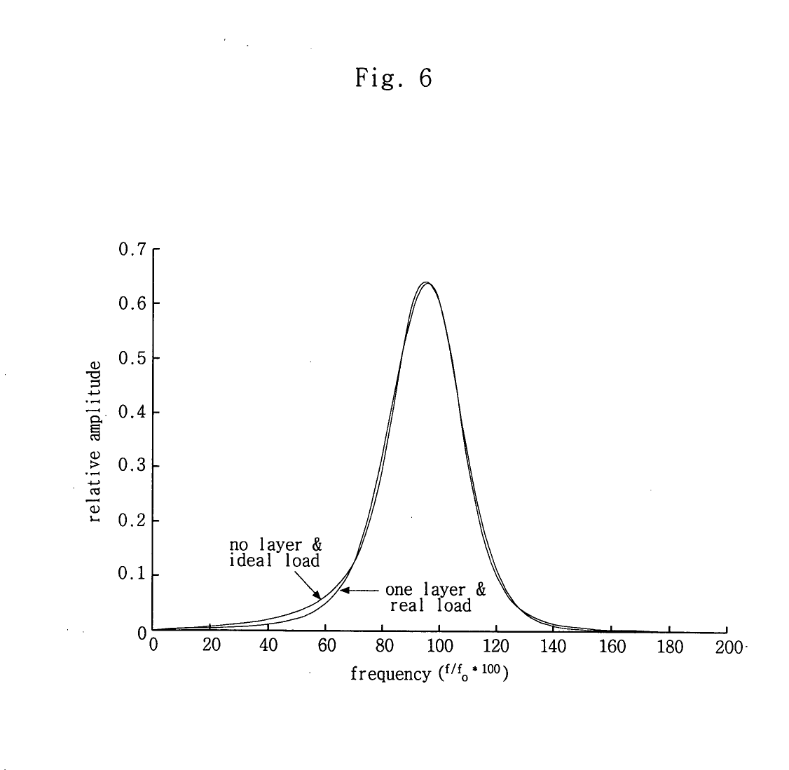

After the optimum value (Z_{f})^{(d)} is determined in the above manner, the case that there is a matching layer is considered. Therefore, the table 2 is obtained, assuming that the impedance (Zᵢ) of each matching layer is (Z_{f})⁽⁰⁾=(Z_{f})^{(d)}. FIG. 6 is a view illustrating the frequency spectrum change of the piezoelectric transducer based on the number of the matching layers when all design parameters except for the matching layers is the values of FIG. 2. Here, zero layer represents that the front load impedance (Zₜ) has the optimum design value (Z_{f})^{(d)}(=0.43 Z_{c}). Therefore, it is known that a desired proximity is obtained in the case of the normal zero layer with only the matching layer of one layer. Therefore, the frequency spectrum with respect to the piezoelectric transducer having the matching layers of two layers and three layers is not shown.

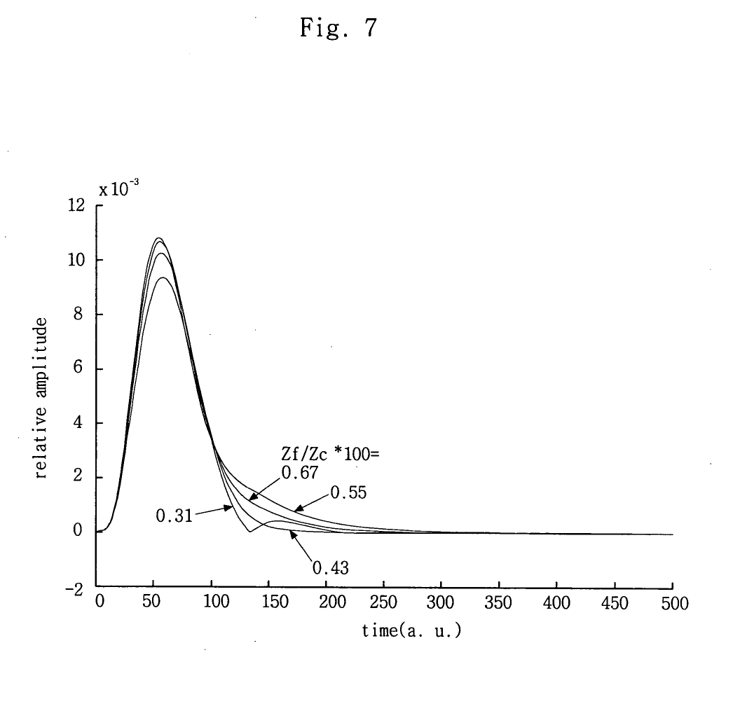

FIG. 7 is a view illustrating the video waveform change of the piezoelectric transducer with the matching layer of one layer based on the front load effective impedance value (Z_{f})⁽⁰⁾ when all design parameters except for the matching layer are the values of FIG. 2. The waveform obtained when (Z_{f})⁽⁰⁾=0.55 Z_{c} is the case that the impedance of the matching layer is selected based on the matching formula of Desilets, and the waveform obtained when (Z_{f})⁽⁰⁾=0.43 Z_{c} is the case that the impedance of the matching layer is selected based a new matching formula. The relative sensitivity and the pulse width of −40 dB are −39.5 dB and 207 in the earlier case, and the latter case has −39.9 dB and 154. Even when the difference of the relative sensitivity is 0.4 dB, but it is known that the latter case has an improved value of 26% (≈(207−154)/207) as compared to the earlier case. In addition, in order to more clearly show the video waveform changes of the piezoelectric transducer based on the value of (Z_{f})⁽⁰⁾, the waveforms with respect to two values (Z_{f})⁽⁰⁾ values (0.31 Z_{c}, 0.67 Z_{c} are included.

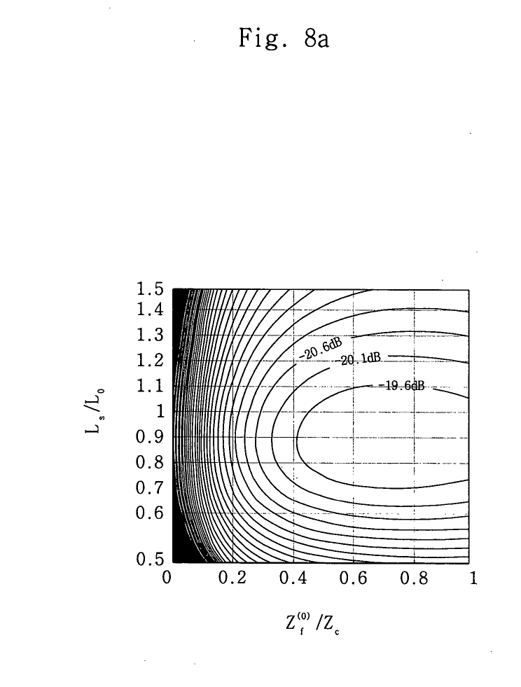

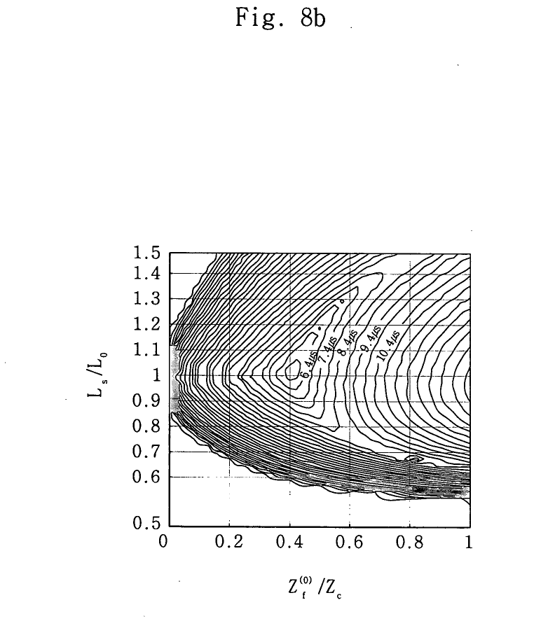

Next, the designing examples for optimizing an angle beam transducer widely used for a destructive evaluation of the welding parts will be described with reference to FIGS. 8 through 10.

The video waveforms of the impulse response for evaluating the sensitivity and pulse width of the transducer are obtained based on the following steps.

(1) A roundtrip transfer function of the transducer is computed using the matrix method proposed by Kervel and Thijssen. At this time, the frequency range computation method and the step sizes of 0<ω<2ω₀ and Δω=0.010ω₀ are preferably used.

(2) The Inverse Fast Fourier Transducer (IFFT) is adapted to the transfer function data. The video waveform is obtained based on an absolute value of a result of the IFFT. Here, the transfer function data comes closer to zero for thereby enhancing an accuracy of the waveform. The amplitude of the waveform is corrected in consideration with the amount of the zero fading.

(3) The maximum time interval is measured between the points of the waveform crossing the peak amplitude and the threshold level of the waveform at the dB scale, and the sensitivity and pulse width of the transducer are characterized. The peak amplitude of 1/10000 (−80 dB) is recommended as a threshold level.

(4) The peak amplitude and pulse width are plotted as a contour on the plane of (Z_{f})⁽⁰⁾/Z_{c} and Lₛ/Z₀ that are a common design parameter with respect to the matching layers of a certain set number. 1/40 step size and a contour interval of 0.5 dB and 0.5 μsec are recommended with respect to both axis using the parameter range of 0<(Z_{f})/Z_{c}<1, 0.5<Lₛ/L₀<1.5.

(5) The optimized design parameter is determined in the region in which the amplitude in the peak amplitude contour map and the depth in the pulse width contour map are duplicated.

(6) The above fourth and fifth steps are performed with respect to the matching layers of a certain number, and the optimum performances of the transducers having a different number of matching layers are compared for thereby determining the optimum number of the matching layers.

(7) The frequency spectrum and RF waveform of the optimized transducer obtained from the absolute value of the transfer function and a real part of the result of the IFFT are plotted, and the designing process is completed.

The above embodiment of the present invention will be described in more detail. As a piezoelectric plate, a disk formed of lead metaniobate (LM) and having a diameter of 12.7 mm is used. The related design parameters are C₀=527 pF, V_{c}=3050 m/sec, Z_{c}=19 Mray1, f₀=2.39 MHz, kₜ=0.3, and A=127 mm². The resonant frequency is selected in such a manner that the optimized transducer has the central frequency of 2.25 MHz. The front load material is transparent synthetic resin (Lucite) having an impedance characteristic of 3.2 Mray1. The back absorption layer is formed of urethane-tungsten carbide compound having an impedance characteristic of 4.5 Mray1. The front load impedance corresponds to about 17% of the piezoelectric plate impedance. The ratio of the back absorption layer with respect to the piezoelectric plate is about 24%.

FIGS. 8A and 8B are views illustrating a peak amplitude contour map and a 80 dB pulse width contour map of the transducer having one matching layer. One peak and one depth are observed on the right center and the plane center of (Z_{f})⁽⁰⁾/Z_{c} and Lₛ/L₀. The size of the peak range is much larger than the size of the depth range, and the gradient of the peak is much smaller than the gradient of the depth. The above thing represents that the optimized design parameter should be determined from the position of the depth in the pulse width contour map.

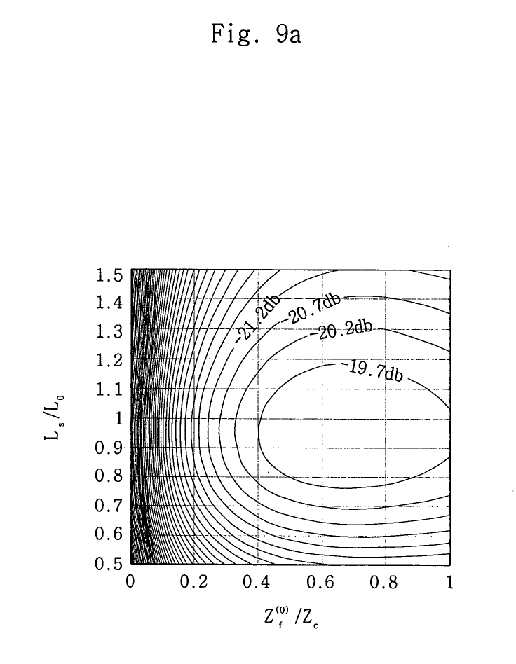

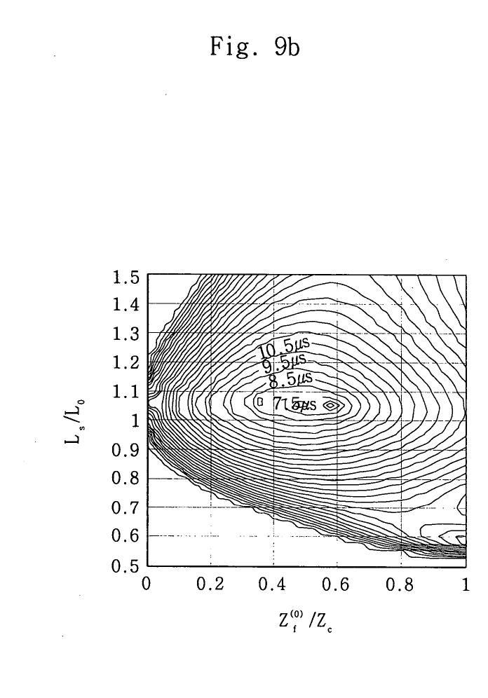

FIGS. 9A and 9B are views illustrating a peak amplitude width contour map and a 80 dB pulse width contour map of the transducer having two matching layers. The peak amplitude contour map is very similar with the case of one matching layer, but the pulse width contour map is slightly different from the case of one matching layer. Here, the most important difference is that the pulse width is more extended based on the increased number of the matching layers. T/he above thing represents that the simple use of the large number of the layers for acoustic matching does not assure the better performance of the transducer. In addition, unsurprisingly, the electric transformer ratio represented in the formula 1 has an asymmetrical characteristic in the frequency spectrum, and all piezoelectric plates do not generate the ultrasonic pulses having standard Gaussian spectra. The use of the optimized series inductor may help the transducer spectrum to be symmetrical in the surrounding portion of the central frequency. In the case that the band pass width of the matching layer is similar with the band pass width of the transducer, the filtering function of the optimized matching layer (s) may be used for enhancing the spectrum of the transducer at a skirt region. The transducer is optimized when the design parameters are n=1, Lₛ=1.08 L₀, and (Z_{f})⁽⁰⁾=0.41 Z_{c}. It is possible to achieve at the matching layer in which the front load impedance Z₁ is 5.0 Mray1 based on the formulas of Table 2.

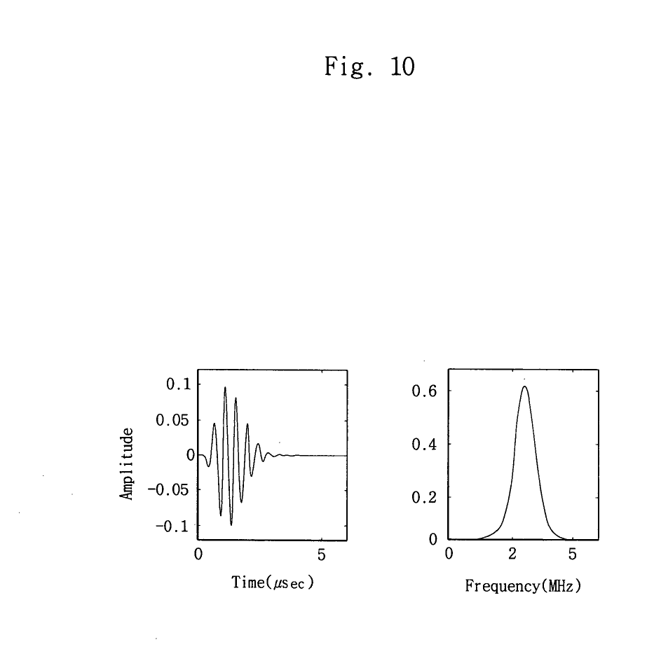

FIG. 10 is a view illustrating a RF waveform and a frequency spectrum of the optimized LM transducer in the embodiments of FIGS. 8 and 9. 6 dB bandwidth is 32% of the central frequency 92.25 MHz), and the sensitivity and 80 dB pulse width are −19.9 dB and 5.5 μsec, respectively.

Namely, in the present invention, the important thing in the design method using the KLM model for optimizing a thickness-mode piezoelectric transducer is that a design parameter having a new free resonant frequency of the front load effective impedance is used instead of the impedance characteristic of the matching layer. In addition, the designing method according to the present invention is simplified and implemented based on a two-dimensional principle with respect to the series inductance parameter and the front load effective impedance parameter irrespective of the number of the matching layers in consideration with the optimized performance of the transducer. When expressing the peak amplitude and the pulse width of the video waveform as a contour map on the two-dimensional plane, there is provided a certain solution from the position of the depth in the pulse width contour map.

As described above, in the optimum designing method of matching layers of a thickness-mode piezoelectric transducer according to the present invention, it is designed concurrently considering the ultrasonic characteristics and electric characteristics of piezoelectric plate, back absorption layer, and acoustic matching layer. Therefore, in the present invention, it is possible to obtain good performance as compared to the conventional ultrasonic transducer designed only inconsideration with the acoustic characteristic.

In addition, in the case that the back absorption layer material is used, it is possible to design and fabricate the transducer having an excellent electric acoustic characteristic based on the optimization of the front load effective impedance. In addition, the front load effective impedance may be flexibly selected based on the purpose of use of the transducer. There is provided a wider range of selection of the materials of the matching layers and the absorption layers. The video waveform is used rather than the RF waveform, so that it is possible to achieve a fixed evaluation of the electric acoustic characteristic (in particular, pulse width) sensitive to the internal structure of the ultrasonic transducer.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

1. A designing method of an acoustic matching layer of a piezoelectric transducer including a piezoelectric plate that is an electric device of a ceramic group capable of converting an electric pulse into a sound wave pulse signal, a back absorption layer that is a sound wave absorption layer for preventing an echo phenomenon of the piezoelectric plate, one or more acoustic matching layers formed in a thin layer structure constructed in order that sound waves generated in the piezoelectric plate can be transferred in the direction of a front load (in the case of nondestructive evaluation, it is referred to a tested object, and in the case of medical diagnosis, it is referred to human body), and an electric matching device that is an electric device for matching an external electric equipment and electric impedance, so that the present invention is well adapted to various fields such as medical diagnosis, underwater detection, nondestructive evaluation, etc., an optimum designing method of matching layers of a thickness-mode piezoelectric transducer that is characterized in that a front load effective impedance when in the direction of load from a front side of the piezoelectric plate as a design parameter when designing acoustic matching layers, and an impedance characteristic of each acoustic matching layer is determined using the following matching formula shown in the following table of which values are obtained based on the formula of:
$$ln \frac{{Z}_{i + 1}}{{Z}_{i}} = {2}^{- n} {C}_{i}^{n} ln \frac{{Z}_{t}}{{Z}_{f}^{( 0 )}}$$
where i=0, . . . , n, Z₀₌(Z_{f})⁽⁰⁾, Zₙ+1=Zₜ, Cᵢⁿ=n!/(n−1)!|!, and

| | TABLE | | |
|---|---|---|---|
| | Impedance | | |
| Number of layers | Z₁ | Z₂ | Z3 |
| 1 | (Z_{f})⁽⁰⁾ (Zₜ)^{1/2} | | |
| 2 | (Z_{f})^{(0)3/4} (Zₜ)^{1/4} | (Z_{f})^{(0)1/4} (Zₜ)^{3/4} | |
| 3 | (Z_{f})^{(0)7/8} (Zₜ)^{1/8} | (Z_{f})⁽⁰⁾ (Zₜ)^{1/2} | (Z_{f})^{(0)1/8} (Zₜ)^{7/8} |

where Z_{f} represents an effective impedance of front load viewed from the front side of the piezoelectric plate, and (Z_{f})⁽⁰⁾ is (Z_{f}) at the free resonant frequency, and (Zₜ) is a front load impedance, and the above results are obtained until n=3.

2. The method of claim 1, wherein when designing the acoustic matching layers of the piezoelectric transducer, a video waveform, not a RF waveform, is used for evaluating sensitivity and pulse width of the piezoelectric transducer.

3. The method of claim 1, wherein an optimized design parameter is determined in a region in which an amplitude in a peak amplitude contour map and a depth in a pulse width contour map are duplicated for optimizing the design parameter.

4. A designing method of an acoustic matching layer of a piezoelectric transducer including a piezoelectric plate that is an electric device of a ceramic group capable of converting an electric pulse into a sound wave pulse signal, a back absorption layer that is a sound wave absorption layer for preventing an echo phenomenon of the piezoelectric plate, one or more acoustic matching layers formed in a thin layer structure constructed in order that sound waves generated in the piezoelectric plate can be transferred in the direction of a front load (in the case of nondestructive evaluation, it is referred to a tested object, and in the case of medical diagnosis, it is referred to human body), and an electric matching device that is an electric device for matching an external electric equipment and electric impedance, so that the present invention is well adapted to various fields such as medical diagnosis, underwater detection, nondestructive evaluation, etc., an optimum designing method of matching layers of a thickness-mode piezoelectric transducer, comprising the steps of:
(1) a step in which a certain front load effective impedance is inputted, and a sensitivity, pulse width and performance index of a piezoelectric transducer are computed based on a KLM model computation;
(2) a step in which a minimum value of a front load effective impedance is selected based on a sensitivity, pulse width and performance index of the piezoelectric transducer computed in the step (1);
(3) a step in which a minimum value of the front load effective impedance is inserted into the matching formula shown in the following table obtained based on the following formula; and
(4) a step in which an impedance computed in the step (3) is determined as an impedance of each layer,
[formula]
$$ln \frac{{Z}_{i + 1}}{{Z}_{i}} = {2}^{- n} {C}_{i}^{n} ln \frac{{Z}_{t}}{{Z}_{f}^{( 0 )}}$$
where i=0, . . . , n, Z₀₌(Z_{f})⁽⁰⁾, Zₙ+1=Zₜ, Cᵢⁿ=n!/(n−1)!|!, and

| | TABLE | | |
|---|---|---|---|
| | Impedance | | |
| Number of layers | Z₁ | Z₂ | Z3 |
| 1 | (Z_{f})⁽⁰⁾ (Zₜ)^{1/2} | | |
| 2 | (Z_{f})^{(0)3/4} (Zₜ)^{1/4} | (Z_{f})^{(0)1/4} (Zₜ)^{3/4} | |
| 3 | (Z_{f})^{(0)7/8} (Zₜ)^{1/8} | (Z_{f})⁽⁰⁾ (Zₜ)^{1/2} | (Z_{f})^{(0)1/8} (Zₜ)^{7/8} |

where Z_{f} represents an effective impedance of front load viewed from the front side of the piezoelectric plate, and (Z_{f})⁽⁰⁾ is (Z_{f}) at the free resonant frequency, and (Zₜ) is a front load impedance, and the above results are obtained until n=3.
